(19) United States
(12) Patent Application Publication
(10) Pub. No.: US 2017/0105288 A1
(43) Pub. Date: Apr. 13, 2017

(54) WIRE ALIGNMENT PROCESS AND DEVICE

(71) Applicant: TYCO ELECTRONICS CORPORATION, Berwyn, PA (US)

(72) Inventors: Huadong WU, Hershey, PA (US); Brian David SMITH, Portland, OR (US); Yasser M. ELDEEB, Harrisburg, PA (US)

(21) Appl. No.: 14/879,528

(22) Filed: Oct. 9, 2015

(51) Int. Cl. H05K 3/34; H05K 1/02; H05K 13/00; G01B 5/25; B23K 3/08

(52) U.S. Cl. CPC H05K 3/34; G01B 5/25; B23K 3/087; H05K 13/0015; H05K 1/028; B25J 11/005

(57) ABSTRACT

Wire-alignment processes and devices are disclosed. A wire-alignment process includes manual loading of a wire-alignment device by positioning and temporary-securing of loading regions of a plurality of wires within an arrangement of grooves of the wire-alignment device. The manual loading of the loading regions produces diverging regions of the plurality of the wires leading to the loading regions and soldering regions oppositely extending from the loading regions. An alignment device includes an arrangement of grooves configured for manual loading of loading regions of wires to produce diverging regions of the wires leading to the loading regions and soldering regions oppositely extending from the loading regions.

### FIELD OF THE INVENTION

The present invention is directed to manufacturing and industrial processes and devices. More particularly, the present invention is directed to wire-alignment processes and devices for robotic ultra-fine wire soldering.

### BACKGROUND OF THE INVENTION

Wire soldering can be a complex process, especially when working with small wires and small termination traces on circuit boards. Soldering can require substantial complicated manual operations almost at the limit of hand-eye coordination systems' capability aided by microscopes to properly align and terminate the small wires. For example, soldering wires of sizes 44 American Wire Gauge (wire diameter of 0.050 millimeters) onto pad traces having widths of 0.050 millimeters, with gaps of 0.050 millimeters between such pad traces, onto a substrate laminate having a thickness of 0.025 millimeters is possible only under microscope.

On average, it takes more than three hours for a well-trained human operator to align the wires and complete such soldering of a typical component having 64 solder joints. The cost associated with the well-trained operator expending such an amount of time results in such components being fairly expensive and limited in supply. In addition, although the well-trained operators are able to produce a high quality component, the soldering quality within the 64 solder joints is inconsistent. Some of the solder joints will have higher quality than other solder joints. The inability to have all of the solder joints at the higher quality is an overall limitation of such techniques.

The traditional hot iron tip soldering process by a human operator involves many complicated maneuver and delicate wire manipulation operations, including: (1) straightening a section of the wire and aligning it onto its corresponding pad trace; (2) holding the aligned wire section in place at clamping points so the to be soldered section is visible and accessible by the hot iron tip (force feedback control is practically excised to keep proper touch during the solder reflowing process when the wire-pad relative position may change); (3) moving hot iron tip to touch the soldered sections and to reflow the already pre-tinned solder material; and (4) removing the hot iron tip quickly, finishing contact once the reflowing is observed to reach required span and the soldered wire is properly seated in place.

Generally, robotic soldering automation has not been utilized in such circumstances due to the complexity and the delicate nature of such components. Robotic soldering automation state of the art technology and commercially available systems are available for soldered components as small as approximately 0.5 mm for conductor lead diameter and/or metallic trace pad width. Such complexity and delicate nature of such components has previously been perceived as rendering robotic soldering automation of such components to be impossible. In addition, prior efforts to utilize robotic soldering automation to align and solder such components had been aborted due to the technical difficulties encountered.

It would, therefore, be beneficial to provide a fine wire termination process that includes one or more improvements in comparison to the prior art. In particular, it would be beneficial to provide a process and device which allows automated alignment of the wires.

### BRIEF DESCRIPTION OF THE INVENTION

In an embodiment, a wire-alignment process includes manual loading of a wire-alignment device by positioning and temporary-securing of loading regions of a plurality of wires within an arrangement of grooves of the wire-alignment device. The manual loading of the loading regions produces diverging regions of the plurality of the wires leading to the loading regions and soldering regions oppositely extending from the loading regions.

In another embodiment, a wire-alignment process includes loading of a wire-alignment device by positioning and temporary-securing of loading regions of wires within an arrangement of grooves of the wire-alignment device, wherein the loading produces diverging regions of the wires leading to the loading regions and soldering regions oppositely extending from the loading regions. The process continues by aligning the grooves to the traces of a printed circuit board to be soldered, then robotically manipulating the soldering regions, and then soldering the soldering regions. The wire-alignment process is devoid of manual manipulation of the wires after the loading.

In another embodiment, an alignment device includes an arrangement of grooves configured for manual loading of loading regions of wires to produce diverging regions of the wires leading to the loading regions and soldering regions oppositely extending from the loading regions.

Other features and advantages of the present invention will be apparent from the following more detailed description, taken in conjunction with the accompanying drawings which illustrate, by way of example, the principles of the invention.

### BRIEF DESCRIPTION OF THE DRAWINGS

FIG. 1 shows a perspective view of an embodiment of a wire-alignment device, according to the disclosure.

FIG. 2 shows a perspective view of a robotic manipulation system arranged to operate in conjunction with the wire-alignment device.

FIG. 3 shows a perspective view of an arrangement of grooves for an embodiment of the wire-alignment device, according to the disclosure.

FIG. 4 shows a perspective view of the loading regions of wires positioned within an arrangement of grooves and bent around the arrangement of grooves within an embodiment of the wire-alignment device according to the disclosure.

FIG. 5 shows a section view of the loading region of a wire positioned within an arrangement of grooves and secured by a pad within an embodiment of the wire-alignment device, according to the disclosure.

FIG. 6 shows a section view of the loading region of a wire positioned within an arrangement of grooves and secured by a pad within an embodiment of the wire-alignment device, according to the disclosure.

Wherever possible, the same reference numbers will be used throughout the drawings to represent the same parts.

### DETAILED DESCRIPTION OF THE INVENTION

Provided are wire-alignment processes and devices. Embodiments of the present disclosure, for example, in comparison to concepts failing to include one or more of the features disclosed herein, permit simplification of wire soldering, permit robotic-aided soldering of smaller wires (for example, wires having a diameter of 0.050 millimeters) onto smaller pad traces (for example, having widths of 0.050 millimeters and gaps of 0.050 millimeters between pad traces) and onto thinner substrates (for example, having a thickness of 0.025 millimeters), permit robotic-aided soldering onto a greater variety of materials (for example, flexible-printed-circuit boards with substrate laminate base material polyimide), permit soldering to be completed in a shorter amount of time (for example, as little as 10 minutes or shorter for a component having 64 solder joints), permit soldering to be completed by less-skilled operators (for example, those capable of loading a wire-alignment device instead of those trained to use a microscopically-enhanced soldering arrangement), permit higher productivity (for example, as compared to processes limited by the number of trained skillful personnel who require long recovery times), permit greater consistency of solder joint quality, or permit any suitable combination thereof.

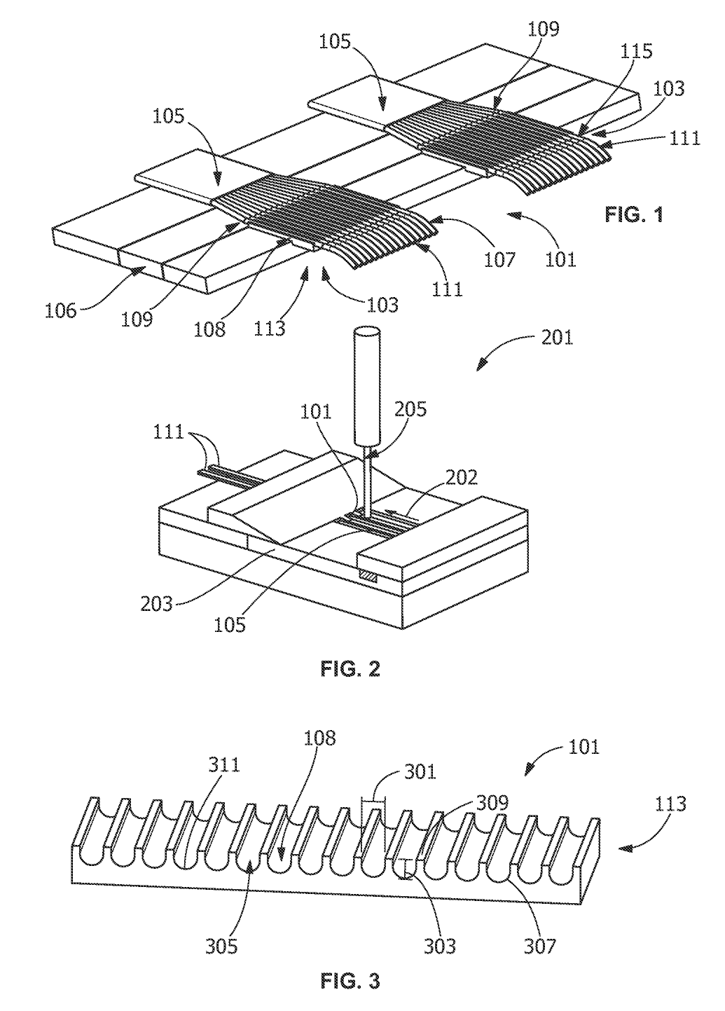

FIG. 1 shows an embodiment of a wire-alignment device 101 capable of being used in a wire-alignment process or in conjunction with a robotic manipulation system 201 (see FIG. 2), according to the disclosure. The wire-alignment process includes manual loading of the wire-alignment device 101 by positioning and temporarily-securing of loading regions 103 of a plurality of wires 111 within an arrangement of grooves 108 of the wire-alignment device 101.

The wires 111 are any suitable power or signal-carrying wire. In one embodiment, the wires 111 have diameters of between 0.045 millimeters and 0.055 millimeters, for example, 0.050 millimeters. In another embodiment, pitch distance between the wires 111 is, for example, between 0.07 millimeters and 0.15 millimeters, such as, 0.1 millimeters.

The manual loading of the loading regions 103 produces diverging regions 109 of the plurality of the wires 111 leading to the loading regions 103 and soldering regions 107 oppositely extending from the loading regions 103. Center-to-center pitch distances and/or diameters of the wires 111 within a wire band region 105 are the same or different compared to the wires in the loading regions 103 and/or the soldering region 107. Different diameters in the wire band region 105 and the loading region 103 may be due to the wires being pre-tinned. In one embodiment, the manual loading is achieved by an individual able to arrange each of the loading regions 103 for each of the wires 111 from the band region 105 into each of the grooves 108, such that only one of the wires 111 from the band region 105 is present in each of the grooves 108 and such that each of the wires 111 from the band region 105 is aligned sequentially within only one of the grooves 108.

The temporary-securing of the loading regions 103 aids the manual loading. As used herein, the phrase “temporary-securing” is intended to encompass concepts that prevent the loading regions 103 from separating from the wire-alignment device 101 during the wire-alignment process or portions of the wire-alignment process. The temporary-securing is capable of utilizing techniques that would secure for a limited time, independent of forces applied, and/or for any suitable time, dependent upon forces applied.

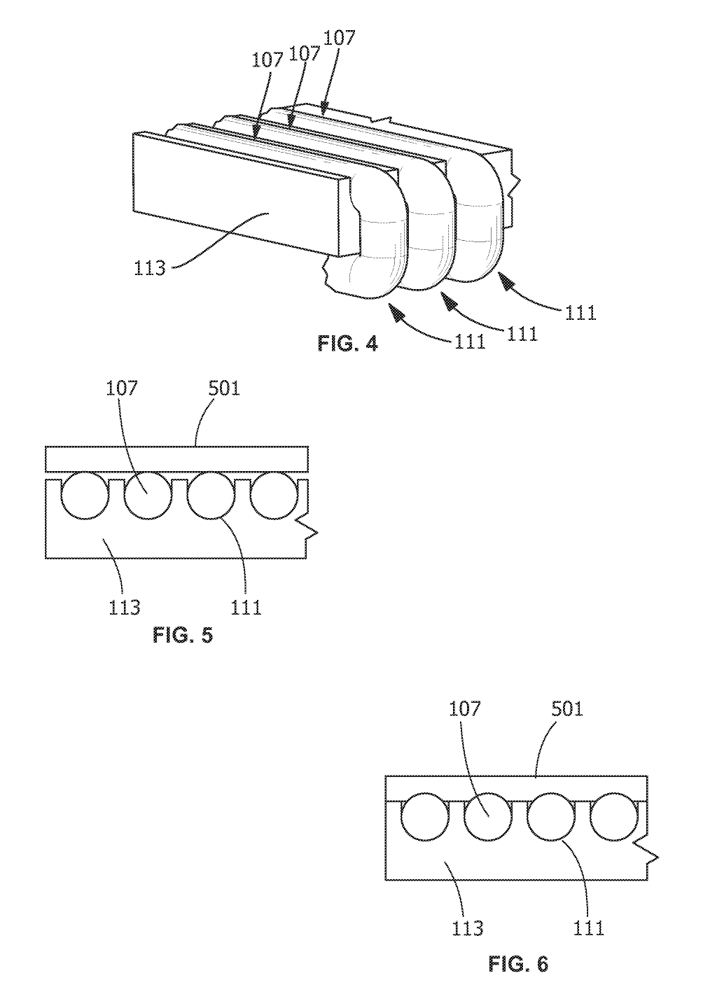

Suitable techniques capable of being used for the temporary-securing include, but are not limited to: i) adhesively coupling the diverging regions 109 and/or any other portion of the plurality of the wires 111 (for example, with an adhesive or a double-sided tape positioned within a recessed region 106 of the wire-alignment device 101) as is shown in FIG. 1; ii) bending a portion of the soldering region 107 around a portion of the wire-alignment device 101 as is shown in FIG. 4; iii) positioning a retention structure 501 upon the wires 111, as is shown in FIGS. 5-6; iv) utilizing known mechanical securing techniques; v) using known chemical securing/adhesive techniques; vi) using known energy-initiated securing techniques; vii) using magnets positioned on top of the grooves 108; or viii) using a combination thereof.

The quantity of the wires 111 and the quantity of the grooves 108 included in the wire-alignment device 101 is based upon the intended application of a component to be produced by the process. Suitable quantities include, but are not limited to, at least 15, at least 30, at least 45, at least 60, 8, 16, 32, 48, 64, 128, or any suitable combination, sub-combination, range, or sub-range therein.

In one embodiment, a plurality of groove arrangements 113 of the grooves 108 is present within the wire-alignment device 101, thereby separating a portion of the wires 111. For example, in one embodiment, 16 of the wires 111 are arranged in 16 of the grooves 108 within a first groove arrangement 113 of the grooves 108 and a second set of 16 of the wires 111 are arranged within an additional arrangement 115 of the grooves 108. As will be appreciated, two arrangements, three arrangements, four arrangements, or more than four arrangements of the additional arrangements 115 are capable of being included within the wire-alignment device 101.

The geometric arrangements and dimensions of the grooves 108 correspond with the geometric arrangements and dimensions of the wires 111, specifically the loading regions 103 of the wires 111. The grooves 108 are all uniform, are substantially uniform, or differ based upon the geometric arrangements and dimensions of the wires 111 to be inserted therein and/or the geometric arrangements and dimensions of the circuitry traces 202 on a substrate 203 to which the wires 111 are soldered.

Referring to FIG. 3, in one embodiment, the grooves 108 have a groove width 301 and a groove depth 303 corresponding with the geometric arrangements and dimensions of the wires 111 and, more specifically, the loading regions 103 of the wires 111. For example, in one embodiment, the grooves 108 include channels 305 having a curved profile 307 with the groove width 301. In one embodiment, the groove width 301 accommodates variations of clinging solder material (not shown) previously pre-tinned within certain tolerances, for example, within 0.005 millimeters of the diameters of the loading regions 103 of the wires 111.

Referring to FIGS. 5-6, the groove depth 303 is based upon an upper surface 309 of the groove arrangement 113 in comparison to a lower surface 311 of the curved profile 307, such that the portions of the wires 111 within the soldering region 107 contact the circuitry traces 202 of the substrate 203.

Referring to FIG. 5, in one embodiment, the loading regions 103 of the wires 111, when positioned within the groove arrangement 113, extend beyond the grooves 108 and are temporarily secured by the retention structure 501. The retention structure 501 applies a force to the loading region 103 and the grooves 108, thereby preventing loosening during the loading process. For example, upon the wire-alignment device 101 being fully settled, as illustrated in FIG. 2, the wires 111 are confined between the grooves and the substrate 203, such as the flexible-printed circuit board, thereby limiting movement of the wires 111 during robotic-manipulation and/or soldering of the wires 111. In this embodiment, the retention structure 501 is removed during the last step of the loading process and does not deflect upon the force being applied during the securing of the wires 111.

Referring to FIG. 6, in one embodiment, the loading regions 103 of the wires 111, when positioned within the groove arrangement 113, extend beyond the grooves 108 and are temporarily secured by the retention structure 501, upon the retention structure 501 applying a force to the loading region 103 and the grooves 108, prior to the wire-alignment device 101 being installed into the soldering position. Upon the wire-alignment device 101 being installed in the soldering position, a clamping force limits movement of the wires 111 during robotic-manipulation and/or soldering of the wires 111. In this embodiment, the retention structure 501 is flexible and deflects upon the force being applied during the securing of the wires 111.

Suitable depths for the grooves 108 include, but are not limited to, being equal to or within 0.005 millimeters of the diameters of the loading regions 103 of the wires 111, being between 85% and 95% the size of the diameters of the loading regions 103 of the wires 111 (for example, by 85%, 90%, or 95% of the value of the diameters), and/or being within a certain tolerance (for example, of 5% or 10% of the nominal diameter value).

The wire-alignment device 101 permits the process to include robotic wire manipulating of the soldering regions 107 of the wire 111, for example, by the robotic manipulation system 201 shown in FIG. 2, thereby resulting in the advantages discussed above. In one embodiment, the soldering regions 107 are insulation-stripped, pre-tinned, and/or otherwise treated and prepared for soldering by any suitable technique. In another embodiment, the robotic manipulating is devoid of manual (human) manipulation. In further embodiments, the process after the manual loading is devoid of such manipulation and/or the process between the manual loading and the soldering is devoid of such manipulation.

In one embodiment, the robotic manipulation system 201 includes a manipulation arm 205 permitting movement as is appropriate for the intended robotic manipulating. In one embodiment, the robotic manipulating is by a computer-assisted robot capable of three degrees-of-freedom movement, with or without location and/or force feedback control. In such embodiments, the robotic manipulating adjusts the position of one or more of the wires 111 (for example, one at a time) at the soldering region(s) 107 in a lateral direction with respect to the loading region(s) 103, in an axial direction with respect to the loading region(s) 103, and/or in a vertical direction generally consistent or opposite with the direction of gravity, for example, with the force feedback control.

Use of the robotic manipulating permits the process and/or the soldering, for example, to the substrate 203, such as the flexible printed circuit board, to be achieved in a briefer period of time and/or by less skilled individuals resulting in a productivity increase of five or more times with respect to the known methods. For example, in one embodiment, the period of time for completing the process and/or the soldering is less than 30 minutes, less than 15 minutes, between 5 minutes and 15 minutes, or any suitable combination, sub-combination, range, or sub-range therein.

As will be appreciated by those skilled in the art, the robotic manipulation system 201 is capable of being utilized in conjunction with any suitable soldering technique. Suitable techniques include, but are not limited to, laser soldering, conventional mechanical hot-iron tip soldering, hot-air soldering, and/or electromagnetic inductance soldering. For example, in one embodiment, the soldering technique includes physically contacting one or more of the soldering regions 107 to reflow the pre-tinned solder material to form a bond joint.

The substrate 203 to be soldered and to receive the wires 111 at the soldering regions 107 is a rigid or flexible material (for example, a thin sheet polyimide material). In one embodiment, the substrate 203 includes a base material laminate and metal pads or traces are chemically printed on a surface of substrate 203. In a further embodiment, the soldering regions 107 match the conductive pad traces of the substrate, such as a printed circuit board, to facilitate aligning of the components being soldered. The metal pads or traces include, but are not limited to, a thin film or layer of any material suitable for soldering to form a bond joint with the substrate 203. Suitable thicknesses for the substrate 203 and/or the flexible-printed circuit board include, but are not limited to, between 0.05 millimeters and 0.06 millimeters.

The process in which the wire-alignment device 101 is utilized includes the following steps: (1) the wires 111 to be soldered are prepared in a ribbonized band and then the tip section is insulation-stripped and pre-tinned; (2) the wires 111 are independently loaded or moved into cooperation with the wire-alignment device 101; (3) the wires 111 in ribbonized band are spread as shown in diverging regions 109 and positioned in grooves 108 to expose the pre-tinned section to be soldered; (4) the wires 111 in the diverging section 109 contact an adhesive or double sided tape located in the recessed region 106 to help arrange and temporally maintain the wires 111 loaded into the grooves 108; (5) the wires 111 are sequentially pushed into the grooves, being temporally held in place (various pushing devices, include, but not limited to, tweezers and small magnets); (6) positioning a retention structure 501, such as, but not limited to, a thin film tape over the wires 111 in the grooves 108, thereby properly positioning with high precision pitch the ends of the wires 111; (7) with the wires properly positioned in the grooves 108, aligning conductive elements of a substrate, such as, but not limited to, a flexible printed circuit board, with the ends of the wires 111; (8) applying appropriate pressure to the wires 111 and/or the substrate to maintain the ends of the wires 11 in position relative to the substrate; and (9) soldering the wires 111 to the substrate by a known soldering technique.

This process and the wire fixture 101 significantly reduces the wire manipulation complexity from that known in the art. This allows the positioning and soldering of the wires to be handled by a micro-robot which has three or more degrees of freedom. As an example, with the wires properly positioned in the grooves 108 and aligned with the conductive elements of a substrate, the process may include the following steps: (1) a robotic end effect wire gripper 601 grips the end of the wire 111, one at a time, to move and hold each wire at a predefined position; (2) a finger-tip gripper fixture extends to grip a small section of the pre-tinned wire, to ensure wire alignment, and to exert a pressure force for the soldering process, using computer vision 602 as its sensing element to allow for slight adjustment of the wire 111; (3) a robotic solder assembly 603 moves the hot iron tip end effect to touch the gripper-held wire section and reflow the pre-tinned solder material to complete the soldering process (other soldering mechanism may be used and moved into proper position to reflow the pre-tinned solder material without departing from the scope of the invention).

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

What is claimed is:

1. A wire-alignment process, comprising:
manual loading of a wire-alignment device by positioning and temporarily-securing of loading regions of a plurality of wires within an arrangement of grooves of the wire-alignment device;
wherein the manual loading of the loading regions produces diverging regions of the plurality of the wires leading to the loading regions and soldering regions oppositely extending from the loading regions.

2. The wire-alignment process of claim 1, wherein the temporary-securing of the loading regions includes adhesively coupling the diverging regions.

3. The wire-alignment process of claim 1, wherein the temporary-securing of the loading regions includes bending a portion of the soldering region around a portion of the wire-alignment device.

4. The wire-alignment process of claim 1, wherein the temporary-securing of the loading regions includes positioning a retention structure upon the loading regions against conductive traces on a printed circuit board positioned to be soldered with the wires.

5. The wire-alignment process of claim 1, further comprising robotically manipulating the soldering regions with force feedback control technology.

6. The wire-alignment process of claim 1, further comprising soldering one or more of the soldering regions with physical contact to reflow solder material and form a bond joint.

7. The wire-alignment process of claim 1, wherein the wire-alignment process is devoid of manual manipulation of the wires after the loading.

8. The wire-alignment process of claim 1, wherein the wire-alignment process is devoid of manual manipulation of the wires between the loading and the soldering.

9. The wire-alignment process of claim 1, wherein the plurality of the wires consists of sixteen of the wires and the arrangement of the grooves consists of sixteen of the grooves.

10. The wire-alignment process of claim 1, wherein the loading of the wire-alignment device further comprises positioning and temporarily-securing loading regions of a second plurality of wires within a second arrangement of grooves of the wire-alignment device.

11. The wire-alignment process of claim 1, wherein the plurality of wires consists of wires having diameters of between 0.045 millimeters and 0.055 millimeters and pitch distances between the wires in the grooves of 0.100 millimeters.

12. The wire-alignment process of claim 1, wherein the plurality of wires are aligned within tolerances such that each of the wires has physical contact with a conductive trace having a width of 0.05 millimeters and a gap of 0.05 millimeters between the wires, the conductive trace being on a double-sided flexible-printed circuit board having a thickness of 0.05 millimeters.

13. The wire-alignment process of claim 1, wherein the arrangement of the grooves comprises channels having a curved profile with a width that is equal to or within 0.005 millimeters of the diameters of the loading regions of the plurality of the wires.

14. The wire-alignment process of claim 1, wherein the arrangement of the grooves comprises channels having a curved profile that extends a depth from a surface of the wire-alignment channel, the depth being 0.005 millimeters less than the diameters of the loading regions of the plurality of the wires.

15. The wire-alignment process of claim 1, wherein the arrangement of the grooves comprises channels having a curved profile that extends a depth from a surface of the wire-alignment channel, the depth being equal to or less than 90% of the diameters of the loading regions of the plurality of the wires and within a tolerance of 5% of the nominal diameter value.

16. The wire-alignment process of claim 1, comprising robotically manipulating the soldering regions and soldering one or more of the soldering regions, wherein the loading, the robotic manipulating, and the soldering are achieved within a combined duration of less than 30 minutes.

17. The wire-alignment process of claim 16, wherein the soldering includes more than 60 solder joints distributed on both sides of a flexible printed circuit board with a thickness of between 0.05 millimeters and 0.06 millimeters.

18. A wire-alignment process, comprising:
manual loading of a wire-alignment device by positioning and temporarily-securing of loading regions of wires within an arrangement of grooves of the wire-alignment device, wherein the manual loading produces diverging regions of the wires leading to the loading regions and soldering regions oppositely extending from the loading regions; then
aligning the arrangement of the grooves to traces of a printed circuit board positioned to be soldered;
robotically manipulating the soldering regions; and then
soldering the soldering regions;
wherein the wire-alignment process is devoid of manual manipulation of the wires after the manual loading.

19. An alignment device, comprising:
an arrangement of grooves configured for manual loading of loading regions of wires to produce diverging regions of the wires leading to the loading regions and soldering regions oppositely extending from the loading regions.
